(19) United States
(12) Patent Application Publication
(10) Pub. No.: US 2026/0135571 A1
(43) Pub. Date: May 14, 2026

(54) METHOD AND DEVICE WITH COMPRESSION

(71) Applicant: SAMSUNG ELECTRONICS CO., LTD., Suwon-si (KR)

(72) Inventors: Jihye PARK, Suwon-si (KR); Jihoon NAM, Suwon-si (KR); Yeongon CHO, Suwon-si (KR); Yoojin KIM, Suwon-si (KR)

(73) Assignee: SAMSUNG ELECTRONICS CO., LTD., Suwon-si (KR)

(21) Appl. No.: 19/380,440

(22) Filed: Nov. 5, 2025

(30) Foreign Application Priority Data
Nov. 12, 2024 (KR) 10-2024-0160364
Jul. 18, 2025 (KR) 10-2025-0097598

(51) Int. Cl. H03M 7/30

(52) U.S. Cl. CPC H03M 7/6011; H03M 7/3073

(57) ABSTRACT

A processor-implemented method including compressing original data using a compression parameter to obtain compressed data, calculating a compression performance index of the compressed data, determining whether the compression performance index satisfies a predetermined condition, and iteratively compressing the original data until the compression performance index satisfies the predetermined condition responsive to the compression performance index not satisfying the predetermined condition.

### CROSS-REFERENCE TO RELATED APPLICATIONS

This application claims the benefit under 35 USC § 119 (a) of Korean Patent Application No. 10-2024-0160364, filed on Nov. 12, 2024, and Korean Patent Application No. 10-2025-0097598, filed on Jul. 18, 2025 in the Korean Intellectual Property Office, the entire disclosure of which is incorporated herein by reference for all purposes.

### BACKGROUND

### 1. Field

The following description relates to a method and device with compression.

### 2. Description of Related Art

Data processing and storage systems may require technology of efficiently storing and processing large amounts of data. Particularly, in high-performance computational tasks such as artificial intelligence (AI) and machine learning, memory capacity and performance are important factors. Various technologies have been introduced to increase memory capacity, but the cost burden and system complexity of processing large amounts of memory remain issues. Memory compression technology may be implemented to solve these issues.

Compression technology may efficiently expand memory capacity by compressing data and reducing memory usage. However, an additional issue of latency introduced during a process of decompressing the compressed data may affect performance. Typical memory compression methods have not effectively processed a trade-off between a compression ratio and decompression latency and thus, may not achieve optimal performance.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a processor-implemented method including compressing original data using a compression parameter to obtain compressed data, calculating a compression performance index of the compressed data, determining whether the compression performance index satisfies a predetermined condition, and iteratively compressing the original data until the compression performance index satisfies the predetermined condition responsive to the compression performance index not satisfying the predetermined condition.

The iteratively compressing may include changing the compression parameter based on the compression performance index, compressing the original data using the changed compression parameter to obtain new compressed data, updating the compression performance index for the new compressed data, and determining whether the updated compression performance index satisfies the predetermined condition.

The determining of whether the compression performance index satisfies the predetermined condition may include determining whether the compression performance index satisfies the predetermined condition within a maximum number of iterative compressions.

The calculating of the compression performance index may include calculating a compression ratio of the compressed data and predicting decompression latency of the compressed data.

The predetermined condition may be determined based on one or more of a number of iterative compressions, the compression ratio, or the decompression latency.

The iteratively compressing may include iteratively compressing the original data until a decompression latency becomes less than or equal to a first threshold value or a number of iterative compressions reaches a maximum number of iterations.

The iteratively compressing may include that, even if the decompression latency becomes less than or equal to the first threshold value, and responsive to a compression ratio becoming less than or equal to a second threshold value, performing compression on the original data using the compression parameter before the compression parameter is changed and terminating the iterative compressions.

The method may include replacing the compressed data with the original data without performing the iteratively compressing responsive to the compression performance index not satisfying the predetermined condition.

The method may include that, after the iteratively compressing is completed, generating a compressed block including final compressed data, and metadata corresponding to the final compressed data, and the metadata may include one or more of information about a compression parameter resulting from the iterative compression, information about a compression ratio threshold value, information about a decompression latency threshold value, and information about a maximum number of iterations.

The calculating of the compression ratio may include comparing a size of the original data to a size of the compressed data to calculate the compression ratio.

The predicting of the decompression latency may include calculating the decompression latency based on characteristics of a compression algorithm and a decompression device.

The compression parameter may include at least one of the compression algorithm, a compression performing unit, a match threshold, or a search window.

The changing of the compression parameter may include setting a compression parameter combination based on one or more of the compression algorithm, the compression performing unit, the match threshold, or the search window and determining the compression parameter combination based on the compression performance index.

In a general aspect, here is provided a non-transitory, computer-readable storage medium storing instructions that, when executed by one or more processors, configure the one or more processors to determine a compression performance index of compressed data, determine whether the compression performance index satisfies a predetermined condition, and iteratively compress original data, the compressed data being based on the original data, until the compression performance index satisfies the predetermined condition responsive to the compression index not satisfying the predetermined condition.

In a general aspect, here is provided an electronic device including one or more processors including processing circuitry and a memory including one or more storage media storing instructions that, when executed individually or collectively by the one or more processors, cause the electronic device to calculate a compression performance index of compressed data, the compressed data being obtained from original data, determine whether the compression performance index satisfies a predetermined condition, and iteratively compress the original data until the compression performance index satisfies the predetermined condition responsive to the compression index not satisfying the predetermined condition.

The electronic device may include an internal buffer configured to receive and store the original data.

The memory may be configured to store one or more of information about a compression ratio threshold value, information about a decompression latency threshold value, or information about a maximum number of iterations.

The instructions, when individually or collectively executed by the one or more processors, may cause the electronic device to change the compression parameter based on the compression performance index, compress the original data using the changed compression parameter to obtain new compressed data, update the compression performance index for the new compressed data, and determine whether the updated compression performance index satisfies the predetermined condition.

The instructions, when individually or collectively executed by the one or more processors, may cause the electronic device to determine whether the compression performance index satisfies the predetermined condition within a maximum number of iterative compressions.

The instructions, when individually or collectively executed by the one or more processors, may cause the electronic device to calculate a compression ratio of the compressed data and predict decompression latency of the compressed data.

Other features and aspects will be apparent from the following detailed description, the drawings, and the claims.

### BRIEF DESCRIPTION OF THE DRAWINGS

FIG. 1A illustrates an example compression system according to one or more embodiments.

FIG. 1B illustrates an example compression engine according to one or more embodiments.

FIG. 2 illustrates an example, method of changing a compression parameter through a compression condition changing device according to one or more embodiments.

FIG. 3 illustrates an example form of compressed data according to one or more embodiments.

FIG. 4 illustrates an example compression performance determination device according to one or more embodiments.

FIG. 5 illustrates an example method with iterative compression based on performance of a compression ratio and decompression latency according to one or more embodiments.

FIG. 6 illustrates an example method with iterative compression based on performance of a compression ratio and decompression latency according to one or more embodiments.

FIG. 7 illustrates an example table representing a combination of compression parameters according to one or more embodiments.

FIG. 8 illustrates an example method with compression according to one or more embodiments.

FIG. 9 illustrates an example electronic device according to one or more embodiments.

FIG. 10A illustrates an example of data flow in an iterative compression mode in detail according to one or more embodiments.

FIG. 10B illustrates an example of data flow in an uncompressed mode in detail according to one or more embodiments.

FIG. 11 illustrates an example method with compression according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment (e.g., as to what an example or embodiment may include or implement) means that at least one example or embodiment exists where such a feature is included or implemented, while all examples are not limited thereto. The use of the terms “example”, “embodiment”, and “example embodiment” herein have a same meaning (e.g., the phrasing ‘in an or one example’ has a same meaning as ‘in an or one embodiment” and ‘in an or one example embodiment’), and “one or more examples” has a same meaning as “one or more embodiments” and “one or more example embodiments”. Still further, each of multiple or all separately described an/one “example”, “embodiment”, “example embodiment”, as well as “examples”, “embodiments”, “example embodiments”, herein may be included, in combination, in a same embodiment in any combination.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Unless otherwise defined, all terms, including technical and scientific terms, used herein have the same meaning as commonly understood by one of ordinary skill in the art to which this disclosure pertains and specifically in the context on an understanding of the disclosure of the present application. Terms, such as those defined in commonly used dictionaries, are to be interpreted as having a meaning that is consistent with their meaning in the context of the relevant art and specifically in the context of the disclosure of the present application, and are not to be interpreted in an idealized or overly formal sense unless expressly so defined herein.

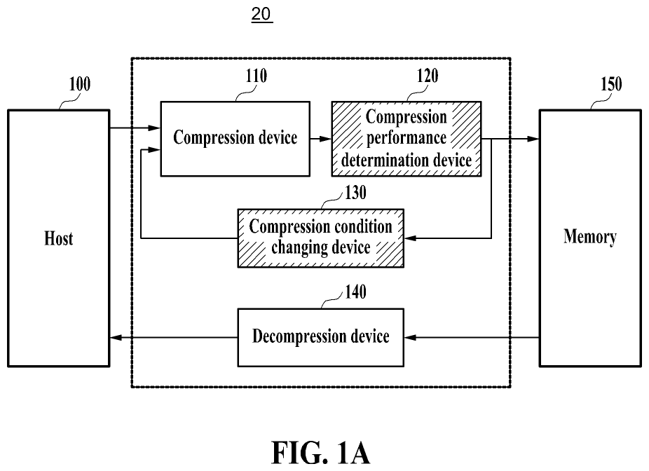

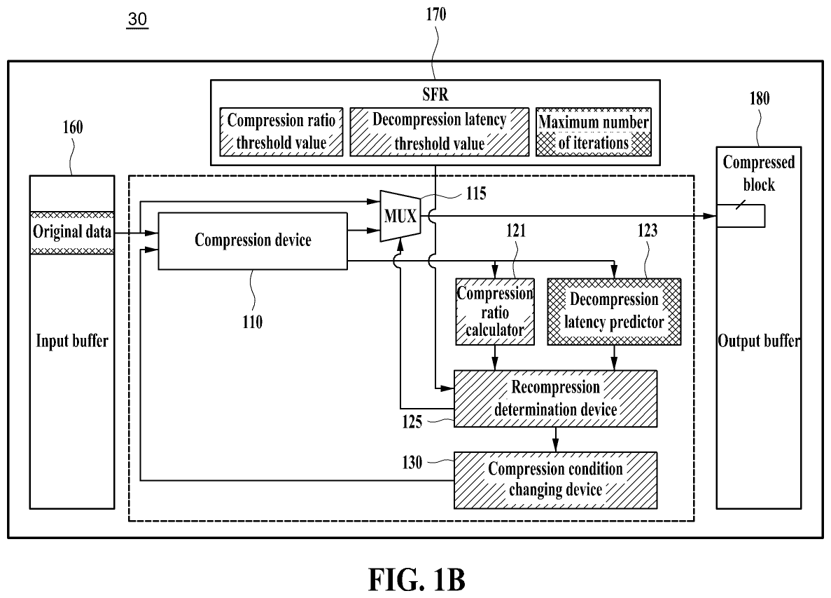

FIG. 1A illustrates an example compression system according to one or more embodiments.

Referring to FIG. 1A, in a non-limiting example, a compression system 20 may include a host 100, a compression engine 10, and a memory 150, wherein the compression engine 10 according to an example may include a compression device 110, a compression performance determination device 120, a compression condition changing device 130, and a decompression device 140. However, not all the shown components are essential. The compression system 20 may be implemented by more or less components than the illustrated components.

The host 100 may transmit original data to the compression device 110, and the compression device 110 may compress this data and store the data in the memory 150. Thereafter, when the host 100 is to use the compressed data, the compressed data may be resto red to an original data form through the decompression device 140 and transmitted to the host 100.

In an example, the compression system's 20 performance may be evaluated based on a performance index. For example, the performance index may be various numerical standards used to evaluate the performance of the compression system 20 and may be an index indicating how efficiently data may be compressed and decompressed. The performance index may function to support optimization of the system by measuring compression quality, speed, and efficiency.

For example, the performance index may include a compression ratio, compression latency, and decompression latency. The compression ratio may be determined by comparing the size of the original data to the size of the compressed data. The compression ratio may be an important index indicating how efficiently the data has been compressed. The compression ratio may be the ratio between an uncompressed data size and a compressed data size. The higher the compression ratio, the smaller the compressed data is compared to the uncompressed data before compression (e.g., the more the data is compressed), which may help save memory space. The compression latency may refer to the time taken to compress the data. The decompression latency may refer to the time taken to restore the compressed data to the original form. Lower decompression latency may refer to faster data restoration, which may be a very important performance index for a system that requires real-time processing. The compression ratio, the compression latency, and the decompression latency may be in a relationship of trade-offs and may require different performance depending on characteristics of the system.

However, compression performance indices are not limited to the examples described above. Besides the compression ratio and the decompression latency, various other indices may be used to evaluate the performance of the compression system 20. For example, performance indices may include memory usage, which is the amount of memory resources that a system uses during compression and decompression processes, processing speed, which represents how fast a compression or decompression operation is performed, and in the case of lossy compression, compression quality, which measures the difference between original data and restored data after compression.

In an example, the compression system 20 may be optimized by repeatedly performing compression until the performance index reaches a desired level.

To adjust the performance during the compression process, the compression performance determination device 120 according to an example may evaluate compression performance, may determine whether to perform additional compression, and when the additional compression is determined to be performed, may change a compression parameter through the compression condition changing device 130. Accordingly, iterative compression may be performed until factors such as the compression ratio and/or the decompression latency satisfy threshold values.

For example, the compression performance determination device 120 according to an example may determine the compression performance index of the compressed data and, based on the compression performance index, may determine whether to perform the additional compression. For example, the compression performance determination device 120 may determine to perform the additional compression when the compression ratio of the compressed data does not satisfy a predetermined standard. The maximum number of iterations and the threshold values of the performance indices used to determine whether to perform the additional compression may be transmitted and received through a special function register (SFR) according to an example.

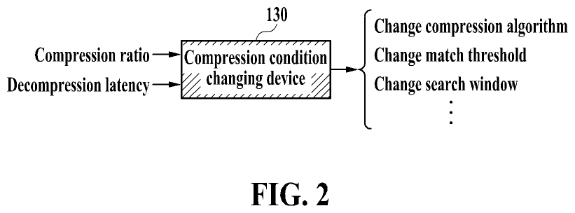

When the additional compression is determined to be performed, the compression condition changing device 130 according to an example may adjust various parameters to increase the compression ratio or reduce the decompression latency. Hereinafter, an example of a method of changing compression parameters through the compression condition changing device 130 is described in detail with reference to FIG. 2.

However, the physical configuration shown in FIG. 1A is only an example and is not limited thereto. For example, the compression engine 10 may be implemented as a single integrated intellectual property (IP) block, and the physical location of the compression engine 10 may vary. The compression engine 10 may exist as a separate chip independent of the host 100, as illustrated in FIG. 1A, may be integrated into a system on chip (SoC) within the host 100, or may be implemented as a portion of an accelerator processor such as a memory controller, a compute express link (CXL) controller, or an XPU (e.g., a neural processing unit (NPU), a data processing unit (DPU), etc.) for artificial intelligence operations.

When the compression engine 10 is integrated into the SoC within the host 100, and when a main processor (e.g., a central processing unit (CPU)) of the host 100 is to store data in the memory 150, the data may be transmitted to the compression engine 10 through a high-speed bus within the SoC instead of being transmitted to the outside. The compression engine 10 may operate as an accelerator or an auxiliary processor within the host 100 and may complete both compression and optimization processes. Only the data (the compressed data or the original data) finally determined may be transmitted to the memory 150 through a memory interface of the host 100. In this case, data transmission between a processor and a compression engine is achieved within a chip, allowing an operation with very low latency.

When the compression engine 10 is implemented as a portion of a memory controller, the host 100 may transmit the uncompressed original data to the memory controller in the same manner as a general memory write operation. The memory controller, which has received the data, may activate the compression engine 10 integrated therein immediately before writing the data to a dynamic random-access memory (DRAM) chip of the memory 150. The compression engine 10 may perform compression and optimization processes on the data and may store the data finally determined in the DRAM. Since the memory controller automatically decompresses and returns the compressed data when the host 100 reads the data, this entire compression process may be performed transparently to the host 100.

Furthermore, in another example, each component of the compression system 20 may be implemented as hardware that performs a specific function. For example, the host 100 may be a CPU or a microprocessor. The compression device 110 and the decompression device 140 may be an encoder circuit and a decoder circuit, respectively, designed to perform a specific compression algorithm. The compression performance determination device 120 may be implemented as hardware logic including an arithmetic logic unit (ALU) and one or more comparators, and the compression condition changing device 130 may be implemented as a control circuit including a state machine or a lookup table (LUT). The memory 150 may be a semiconductor memory device such as DRAM. Such hardware components may be designed as an application-specific integrated circuit (ASIC) or implemented on a field-programmable gate array (FPGA).

FIG. 1B illustrates an example compression engine according to one or more embodiments. The configuration and operation described with reference to FIG. 1A may be applied in a similar manner or with some modifications to the example of FIG. 1B. Therefore, in the description provided with reference to FIG. 1B, detailed descriptions of parts that are substantially similar to those already described with reference to FIG. 1A may be omitted.

Referring to FIG. 1B, in a non-limiting example, a compression engine 30 may include an input buffer 160, the compression device 110, a multiplexer (MUX) 115, a compression ratio calculator 121, a decompression latency predictor 123, a recompression determination device 125, the compression condition changing device 130, an SFR 170, and an output buffer 180. However, not all of the illustrated components are essential components. The compression engine 30 may be implemented with more or fewer components than those illustrated. For example, FIG. 1B focuses on iterative compression and performance determination processes, which are the core of the present disclosure. For clarity of description, some components, such as the decompression device 140 used when reading data, may be omitted.

In an example, the input buffer 160 may be a storage space that temporarily stores the original data to be compressed. When iterative compression is performed, the input buffer 160 may reuse the stored original data instead of receiving the original data from the outside each time, thereby increasing compression efficiency. For example, the input buffer 160 may be implemented as high-speed memory such as static random-access memory (SRAM). In this case, since the input buffer 160 may be configured to be located within the compression engine, the input buffer 160 may also be referred to as an “internal buffer.”

In an example, the compression device 110 may receive the original data from the input buffer 160, may perform compression according to a provided compression parameter, and may generate the compressed data. The generated compressed data may be transmitted to the MUX 115 and the compression ratio calculator 121.

For example, referring to FIG. 1A, the compression performance determination device 120 may include the compression ratio calculator 121, the decompression latency predictor 123, and the recompression determination device 125.

In an example, referring back to FIG. 1B, the compression ratio calculator 121 may calculate the compression ratio of the compressed data. For example, the compression ratio calculator 121 may calculate the compression ratio by comparing the size of the original data to the size of the compressed data generated by the compression device 110.

The decompression latency predictor 123 according to an example may be a functional block that predicts the time required to restore the compressed data back to the original data. The decompression latency predictor 123 may analyze structural characteristics of the compressed data, such as the type of compression algorithm used or a ratio of literal data to redundant data in the compressed data, and may estimate operation quantity required for decompression, thereby predicting latency. An example method of predicting decompression latency is described in greater detail below.

In an example, the SFR 170 may be a register that stores a value for setting a target condition for a compression operation. The SFR 170 may include setting values such as a compression ratio threshold value representing a target minimum compression ratio, a decompression latency threshold value representing a maximum allowable decompression time, and a maximum number of iterations representing a maximum allowable number of iterative compressions. The setting values stored in the SFR 170 may be dynamically changed by an application program of a system or a user.

In an example, the recompression determination device 125 may comprehensively determine compression performance and may determine whether to perform additional compression. The recompression determination device 125 may compare the compression ratio received from the compression ratio calculator 121 and the predicted latency received from the decompression latency predictor 123 to respective threshold values stored in the SFR 170. As a result of comparing, when current compression performance is determined not to meet the target condition, the recompression determination device 125 may transmit a signal to the compression condition changing device 130 to initiate an iterative compression process.

In an example, the compression condition changing device 130 may determine a new compression parameter that may improve the current compression performance. Based on the determination result of the recompression determination device 125, the compression condition changing device 130 may change the compression parameter, for example, by increasing the size of a search window when the compression ratio needs to be increased or by selecting a simpler compression algorithm when the decompression latency needs to be decreased. The changed compression parameter may then be transmitted to the compression device 110 so that recompression may be performed on the original data stored in the input buffer 160.

In an example, the MUX 115 may be a data selector that selects and outputs one of multiple inputs. The MUX 115 may select one of initial compressed data and the compressed data finally generated through the iterative compression, based on a control signal from the recompression determination device 125, and may transmit the selected data to the output buffer 180.

In an example, the output buffer 180 may be a space for storing the finally determined data. The data stored in the output buffer 180 may have the form of a compressed block. The compressed block may include a data payload including actual compressed data and metadata including information required for decompression of the data. The metadata may include, for example, information such as the type of the compression parameter used for final compression, the compression algorithm, and a compression performing unit.

FIG. 2 illustrates an example, method of changing a compression parameter through a compression condition changing device according to one or more embodiments. The description provided with reference to FIGS. 1A and 1B may also apply to FIG. 2.

Referring to FIG. 2, in a non-limiting example, the compression condition changing device 130 may change a compression parameter value by considering a compression ratio and decompression latency.

A compression parameter according to an example may refer to variables used to adjust or optimize performance during data compression. The compression parameter may affect performance indices such as a compression ratio, processing speed, and decompression latency. Performance of a data compression system (e.g., compression systems 20 and 30) may be optimized by setting appropriate parameters.

For example, the compression parameter may include at least one of a compression algorithm, a compression performing unit, a match threshold, and/or a search window.

The compression algorithm used may be a key parameter in the compression process. Since different compression algorithms may analyze and process data patterns differently, it may be important to select an appropriate algorithm for particular data. The compression algorithm may include, for example, a Lempel-Ziv (LZ) algorithm, Huffman coding, and Burrows-Wheeler transform (BWT).

The compression performing unit according to an example may represent the size of data processed at one time when compressing data. A larger compression performing unit may result in a higher compression ratio but may increase decompression latency. On the contrary, a smaller compression performing unit may result in higher compression speed but may decrease the compression ratio.

The match threshold according to an example may be a parameter that specifies the minimum length of a duplicate data block for compression. A smaller match threshold may result in compression of shorter data duplication but may lower compression efficiency. On the contrary, a larger match threshold may result in higher compression efficiency, but compression may not be performed properly when there is little data duplication.

In an example, the search window may refer to the size of a data area in which data is searched for to find duplicate patterns during data compression. A larger search window may result in finding more duplicate data but may lower processing speed.

However, the compression parameters are not limited to the examples described above. In addition to the compression algorithm, the compression performing unit, the match threshold, and the search window, various indices may be used as the compression parameters. For example, the compression parameters may include a compression level, which is a parameter that adjusts the strength of data compression, a coding method, in which the coding method used in data compression is a compression parameter, and a data sampling ratio, which is a parameter that determines how finely data is sampled for compression.

The compression condition changing device 130 may dynamically change the compression parameters according to a degree to which the compression condition changing device 130 is to change the compression parameters by comparing the performance indices obtained after compression to the threshold value. For example, when the compression condition changing device 130 intends to increase the compression ratio, the compression condition changing device 130 may reduce the match threshold, may increase the size of the search window, and/or may change multiple parameters simultaneously.

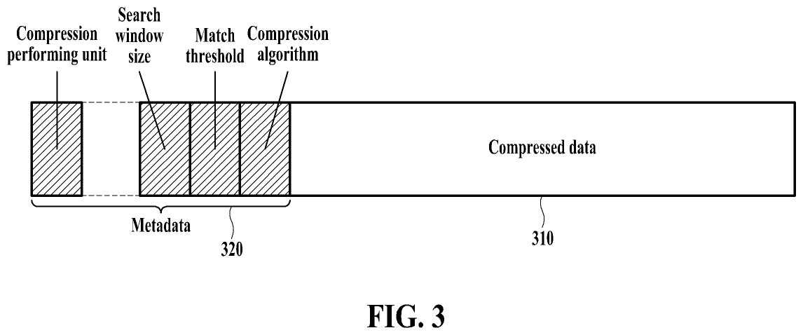

FIG. 3 illustrates an example form of compressed data according to one or more embodiments. The description provided with reference to FIGS. 1A to 2 may also apply to FIG. 3.

Referring to FIG. 3, in a non-limiting example, a compressed block stored in an output buffer (e.g., the output buffer 180 of FIG. 1B) may be configured to include metadata 320 and compressed data 310 corresponding to a data payload including actual compressed original data.

In an example, the metadata 320 may include parameter information used in a compression process and may provide information to be used to restore compressed data to an original state.

In an example, the metadata 320 may include various parameters such as a compression performing unit, the size of a search window, a match threshold, and a compression algorithm used. These parameters may provide information used to decompress the compressed data, thereby accurately restoring data during a restoration process. Each parameter may have a significant impact on performance during the compression process. For example, the size of the search window may determine a range in which duplicate data is found during compression, and the match threshold may specify the minimum length of a duplicate data block. These values may be repeatedly changed depending on intended performance of a system, and changed parameters may be recorded as the metadata 320.

The size of the metadata 320 may be very small compared to the size of the compressed data 310, and therefore overhead added due to the metadata 320 may not be large. Therefore, the presence of the metadata 320 may have a minimal impact on overall performance of the system, and efficient performance may be maintained during the compression and decompression processes.

When decompressing the compressed data, a decompression device (e.g., the decompression device 140 of FIG. 1) may set a compression algorithm and a parameter by referring to the metadata 320 and may perform accurate data restoration. Accordingly, the compression method and device of one or more examples may enable performance optimization during repeated compression and decompression processes and may provide flexibility for application to various systems.

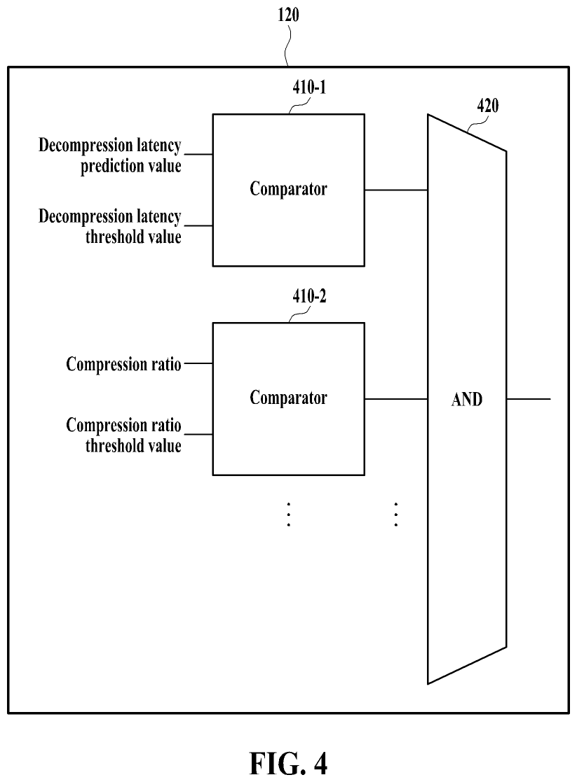

FIG. 4 illustrates an example compression performance determination device according to one or more embodiments. The description provided with reference to FIGS. 1A to 3 may also apply to FIG. 4.

Referring to FIG. 4, in a non-limiting example, the compression performance determination device 120 may evaluate compression performance and may determine whether to perform additional compression. In order to determine whether to perform iterative compression, the compression performance determination device 120 may identify first a compression ratio and decompression latency after compression is performed. The compression ratio may be determined by comparing the size of compressed result data to the size of original data.

On the contrary, decompression latency may be often difficult to measure directly and may instead be predicted through determinations. Decompression latency prediction may vary depending on a compression algorithm used. Furthermore, the decompression latency prediction may vary depending on characteristics of the decompression device 140. Since decompression speed may vary depending on a decompression algorithm used by the decompression device 140, the decompression latency may be predicted based on this. For example, a compression algorithm of the LZ family may compress duplicate data into literal, length, and distance (LLD) blocks, and the decompression latency may be estimated based on the characteristics of this algorithm. A latency determination method may vary depending on the block shape of each algorithm, and in the present disclosure, the decompression latency may be predicted according to such an algorithm.

In an example, the decompression latency prediction may be performed by analyzing the structure of the compressed data and reflecting hardware characteristics of the decompression device 140. The decompression device 140 may be characterized in advance by the time required to process a specific instruction or a data type. For example, a clock cycle required to process literal data and a clock cycle required to copy redundant data may be defined differently.

For example, a description of a case of using an LZ family of algorithms may be provided. Data compressed using an LZ algorithm may generally be configured in a combination of literals (uncompressed original data bytes) and pointers (redundant data information representing a length and a distance). The decompression latency predictor 123 may analyze a compressed data stream generated by the compression device 110 and may respectively count the total number of literals and pointers in the entire data.

When a unit processing time required to process one literal and a unit processing time required to process one pointer are provided in advance, the overall decompression latency may be calculated by adding up values obtained by multiplying each total number by the corresponding unit processing time. Here, each unit processing time value may be a predetermined constant depending on hardware design of the decompression device 140 or a variable value depending on the length of data directed to by the pointer. This prediction method may be similarly applied to other compression algorithms. For example, in the case of Huffman coding, the overall latency may be predicted based on decoding time according to the code length of each symbol, and in the case of run-length encoding, the overall latency may be predicted based on the length of iterative data.

A comparator 410-1 may compare a decompression latency prediction value to a set threshold value and a comparator 410-2 may compare a compression ratio to another set threshold value. The comparator 410-1 may compare the decompression latency prediction value to a decompression latency threshold value, and the comparator 410-2 may compare the compression ratio to a compression ratio threshold value. As described above, the decompression latency threshold value and the compression ratio threshold value may be transmitted via an SFR according to an example. Although FIG. 4 shows that the decompression latency and the compression ratio are used as compression performance indices, various indices other than the compression ratio and the decompression latency may be used to evaluate the performance of a compression system, as described above. In this case, a comparator corresponding to each compression performance index may be used.

In an example, results from the comparator 410-1 and the comparator 410-2 may be transmitted to an AND gate 420. The AND gate 420 may determine not to perform additional compression when both performance indices satisfy the threshold values. That is, the iterative compression may be terminated only when the decompression latency is less than the decompression latency threshold value and the compression ratio is greater than or equal to the compression ratio threshold value. On the contrary, when even one condition is not satisfied (e.g., when the decompression latency is greater than or equal to the decompression latency threshold value and/or the compression ratio is less than the compression ratio threshold value), it may be determined that the additional compression is to be performed, and an iterative compression condition changing device may be activated to change compression parameters and perform the compression again to optimize performance.

However, FIG. 4 shows only an example of the compression performance determination device 120, and the compression performance determination device 120 may be implemented in other forms. For example, the compression performance determination device 120 may be configured to transfer original data, not compressed data, to the memory 150 when both performance indices do not satisfy the threshold value.

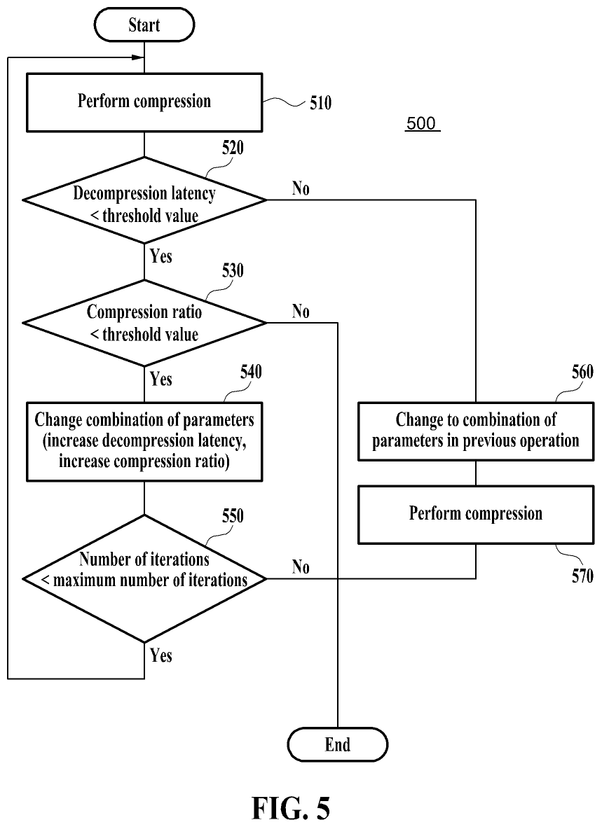

FIG. 5 illustrates an example method with iterative compression based on performance of a compression ratio and decompression latency according to one or more embodiments. The description provided with reference to FIGS. 1 to 4 may also apply to FIG. 5.

Operations 510 to 570 of method 500 may be performed in the shown order and manner. However, the order of one or more of the operations may be changed, one or more of the operations may be omitted, two or more of the operations may be performed in parallel or simultaneously, and/or other operations may be additionally performed without departing from the spirit and scope of the example embodiments described herein.

Referring to FIG. 5, in a non-limiting example, method 500 may perform iterative compression when an initial compression result has a compression ratio lower than a threshold value and decompression latency also lower than a threshold value.

In an example, a compression performance determination device (e.g., compression performance determination device 120) may perform compression in operation 510. The compression performance determination device may then first compare whether decompression latency is less than a threshold value (e.g., the decompression latency threshold value), in operation 520. When the decompression latency is less than the threshold value, the compression performance determination device may compare a compression ratio to another threshold value (e.g., the compression ratio threshold value), in operation 530.

In an example, when the compression ratio is less than the threshold value, a compression condition changing device (e.g., compression condition changing device 130) may adjust compression parameters such that the compression ratio may be increased, by changing a combination of parameters, in operation 540. During this process, the decompression latency may increase due to a trade-off relationship.

Subsequently, in an example, the compression condition changing device may confirm whether the number of iterations has reached the maximum number of iterations, in operation 550. When the maximum number of iterations has not been reached, a compression device (e.g., compression device 110) may perform compression again with the changed parameters, and this process may be repeated until the compression ratio satisfies the threshold value.

However, in an example, when the decompression latency is greater than or equal to the threshold value during the iterative compression process in operation 520, the compression condition changing device may revert to a previously used combination of parameters to optimize performance in operation 560. Here, a compression performance determination device (e.g., compression performance determination device 120) may change the combination of compression parameters to the combination of parameters used in a previous operation, in operation 560, and the compression device may proceed with the compression again using the changed combination of compression parameters, in operation 570. To this end, the compression system may store the combination of parameters used in the previous operation.

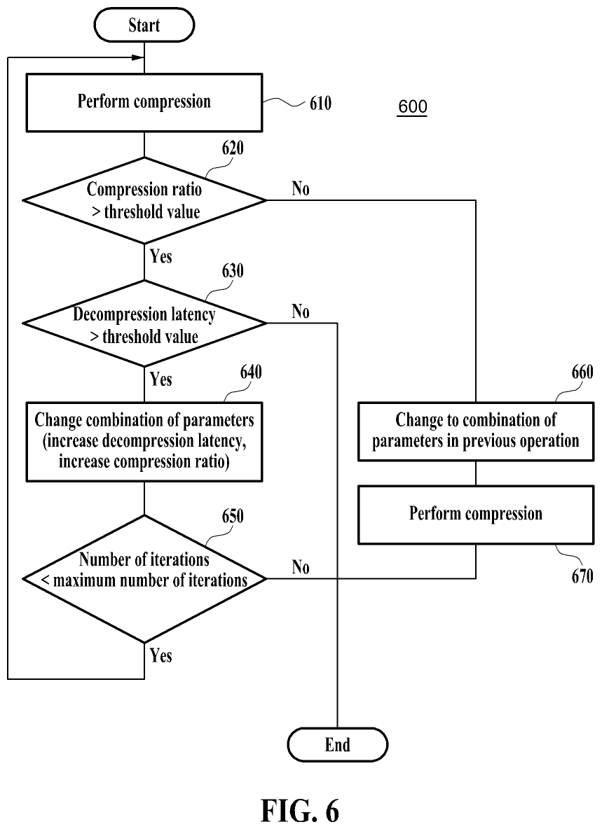

FIG. 6 illustrates an example method with iterative compression based on performance of a compression ratio and decompression latency according to one or more embodiments. The description provided with reference to FIGS. 1 to 4 may apply to FIG. 6 likewise. Operations 610 to 670 of method 600 may be performed in the shown order and manner. However, the order of one or more of the operations may be changed, one or more of the operations may be omitted, two or more of the operations may be performed in parallel or simultaneously, and/or other operations may be additionally performed without departing from the spirit and scope of the example embodiments described herein.

Referring to FIG. 6, in a non-limiting example, the method 600 may perform iterative compression when an initial compression result has a compression ratio greater than a threshold value and decompression latency also greater than a threshold value.

In an example, a compression performance determination device (e.g., compression performance determination device 120) may perform compression in operation 610 and then may first compare whether a compression ratio is greater than a threshold value (e.g., the compression ratio threshold value), in operation 620. When the compression ratio is greater than the threshold value, the compression performance determination device may compare whether decompression latency is greater than another threshold value (e.g., the decompression latency threshold value), in operation 630.

When the decompression latency is greater than the threshold value, a compression condition changing device (e.g., compression condition changing device 130) may change a combination of parameters and may adjust compression parameters such that the decompression latency is reduced, in operation 640. During this process, the compression ratio may decrease due to a trade-off relationship.

Subsequently, in an example, the compression condition changing device may confirm whether the number of iterations has reached the maximum number of iterations, in operation 650. When the maximum number of iterations has not been reached, a compression device (e.g., compression device 110) may perform compression again with the changed parameters, and this process may be repeated until the compression ratio satisfies the threshold value.

However, in an example, when the compression ratio is less than or equal to the threshold value during the iterative compression process in operation 630, the compression condition changing device may change the combination of compression parameters to the combination of parameters used in a previous operation, in operation 660, and the compression device 110 may proceed with the compression again using the changed combination of compression parameters, in operation 670. To this end, the compression system may store the combination of parameters used in the previous operation.

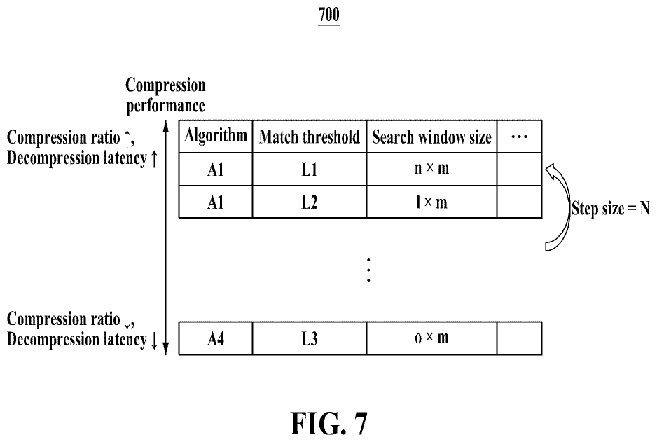

FIG. 7 illustrates an example table representing a combination of compression parameters according to one or more embodiments. The description provided with reference to FIGS. 1A to 6 may also apply to FIG. 7.

Referring to FIG. 7, in a non-limiting example, a compression parameter combination table 700 may provide combinations including various parameters such as a compression algorithm, a compression performing unit, a match threshold, and a search window and may be used as a tool for predicting an impact on compression performance in advance. The compression parameter combination table 700 may have a structure that considers performance of each combination, and a combination may be selected according to desired or intended performance.

Before the compression is performed, an initial parameter combination may be set depending on an intended performance (e.g., a predetermined intended performance). When the performance is not satisfied after the compression is performed, the compression condition changing device 130 may be used to switch to another parameter combination in the table. Here, performing compression with a different parameter combination may not only include performing compression with a new parameter combination on original data stored in an input buffer, but also performing compression again on previously compressed data.

A parameter combination may be changed in a manner of moving according to a predetermined step size in the compression parameter combination table 700. When a compression ratio is to be increased, a combination at the top of the table may be selected, and when decompression latency is to be decreased, a combination at the bottom may be selected.

In addition, a performance difference when changing the parameter combination may be an important standard for selecting a parameter combination to be used in the next iteration compression. The compression condition changing device 130 may control performance changes by adjusting the step size. For example, the compression condition changing device 130 may finely adjust performance by setting a large step size when a larger performance change is desired and reducing the step size when a smaller performance change is desired.

When a number of parameter combinations is less than the maximum number of iterations, an optimal performance may be achieved by applying as many combinations as possible. However, when the number of parameter combinations exceeds the maximum number of iterations, it may become difficult to find an optimal combination and the iteration may be stopped. In this case, a binary search technique or a method of determining a step size considering the maximum number of iterations by setting upper and lower limits may be used.

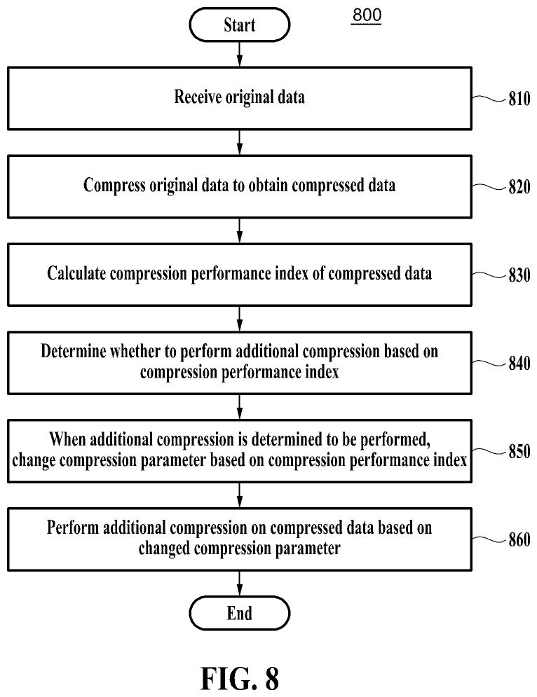

FIG. 8 illustrates an example method with compression according to one or more embodiments. The description provided with reference to FIGS. 1 to 7 may also apply to FIG. 8.

Operations 810 to 860 of method 800 may be performed in the shown order and manner. However, the order of one or more of the operations may be changed, one or more of the operations may be omitted, two or more of the operations may be performed in parallel or simultaneously, and/or other operations may be additionally performed without departing from the spirit and scope of the example embodiments described herein.

Referring to FIG. 8, in a non-limiting example, method 800 may include, in operation 810, a compression device (e.g., compression device 110) may receive original data. The compression device may receive the original data from a host (e.g., host 100).

In an example, in operation 820, the compression device may compress the original data to generate compressed data.

In an example, in operation 830, a compression performance determination device (e.g., compression performance determination device 120) may determine a compression performance index of the compressed data. The compression performance determination device may determine a compression ratio of the compressed data and decompression latency of the compressed data.

In an example, in operation 840, the compression performance determination device may determine whether to perform additional compression based on the compression performance index. The compression performance determination device may compare the compression performance index to a threshold value and based on a comparison result, may determine whether to perform the additional compression. The compression performance determination device may compare the compression ratio of the compressed data to a first threshold value and may compare the decompression latency of the compressed data to a second threshold value. The compression performance determination device may determine not to perform the additional compression when the compression ratio is greater than or equal to the first threshold value and the decompression latency is less than or equal to the second threshold value.

In an example, in operation 850, when the additional compression is determined to be performed, a compression condition changing device (e.g., compression condition changing device 130) may change a compression parameter based on the compression performance index. The compression condition changing device may change at least one of a compression algorithm, a compression performing unit, a match threshold, and/or a search window.

In an example, in operation 860, the compression device may perform the additional compression on the compressed data based on the changed compression parameter.

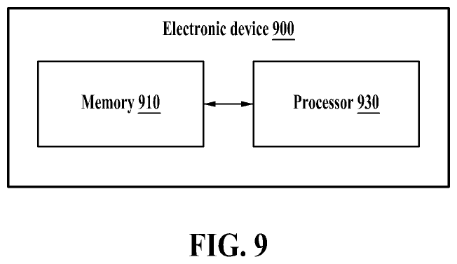

FIG. 9 illustrates an example electronic device according to one or more embodiments. The description provided with reference to FIGS. 1A to 8 may apply to FIG. 9 likewise. For example, an electronic device 900 may include a compression system described with reference to FIG. 1A.

Referring to FIG. 9, in a non-limiting example, the electronic device 900 may include a memory 910 (e.g., one or more memories) and a processor 930 (e.g., one or more processors).

The memory 910 may store instructions (or programs) executable by the processor 930. For example, the instructions include instructions for performing an operation of the processor 930 and/or an operation of each component of the processor 930. For example, the memory 910 may be or include a non-transitory computer-readable storage medium storing code that, when executed by the processor 930, configures the processor 930 to perform any one, any combination, or all of the operations and/or methods disclosed herein with reference to FIGS. 1-8.

The memory 910 may be implemented as a volatile memory device or a non-volatile memory device.

The volatile memory device may be implemented as DRAM, SRAM, thyristor RAM (T-RAM), zero capacitor RAM (Z-RAM), and/or twin transistor RAM (TTRAM).

The non-volatile memory device may be implemented as electrically erasable programmable read-only memory (EEPROM), flash memory, magnetic RAM (MRAM), spin-transfer torque (STT)-MRAM, conductive bridging RAM (CBRAM), ferroelectric RAM (FeRAM), phase-change RAM (PRAM), resistive RAM (RRAM), nanotube RRAM, polymer RAM (PoRAM), nano floating gate memory (NFGM), holographic memory, a molecular electronic memory device, and/or insulator resistance change memory.

The processor 930 may process data stored in the memory 910. The processor 930 may execute computer-readable code (e.g., software) stored in the memory 910, and instructions triggered by the processor 930.

The processor 930 may be a data processing device implemented by hardware including a circuit having a physical structure to perform desired operations. For example, the desired operations may include code or instructions in a program.

The hardware-implemented data processing device may include, for example, a microprocessor, a CPU, a processor core, a multi-core processor, a multiprocessor, an ASIC, and an FPGA.

The processor 930 may obtain compressed data by compressing original data using a compression parameter, may calculate a compression performance index of the compressed data, may determine whether the compression performance index satisfies a predetermined condition, and when the compression performance index does not satisfy the predetermined condition, may iteratively compress the original data until the compression performance index satisfies the predetermined condition.

The processor 930 may perform operations of the compression system described with reference to FIGS. 1A to 8 in substantially the same manner. Accordingly, a further description thereof will be omitted herein.

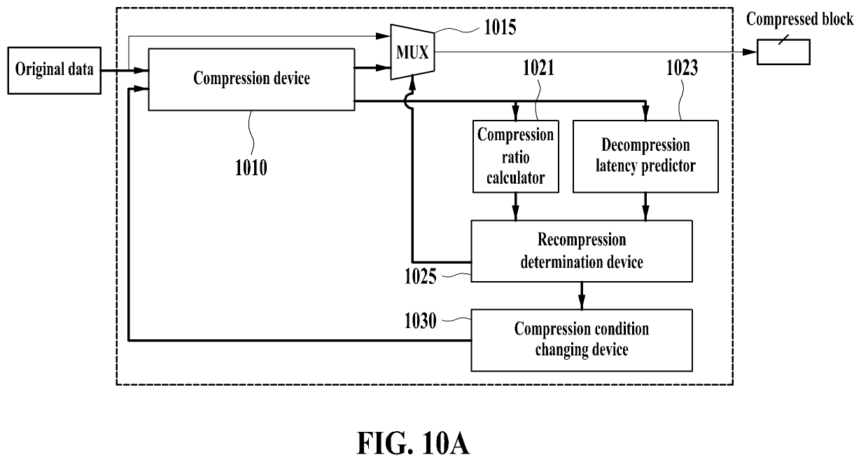

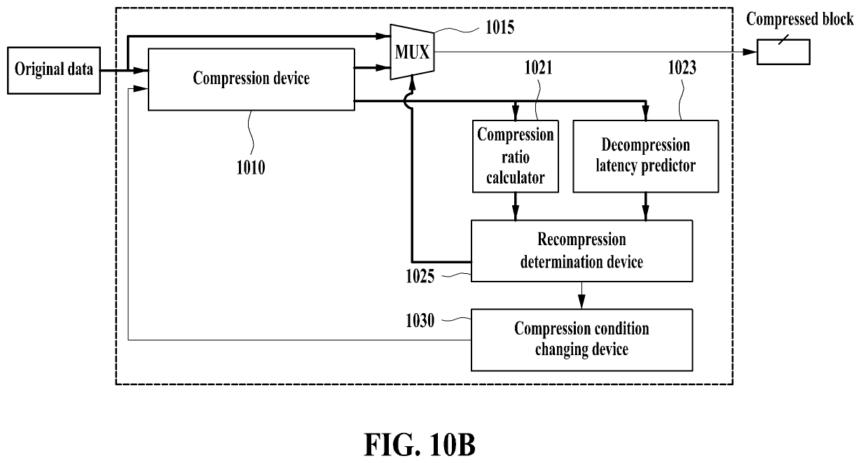

FIG. 10A illustrates an example of data flow in an iterative compression mode in detail according to one or more embodiments. The configuration and operation described with reference to FIGS. 1A to 9 may be applied in a similar manner or with some modifications to the example of FIG. 10A. Therefore, in the description of FIG. 10A, a detailed description of portions substantially similar to those described above with reference to FIGS. 1A to 9 may be omitted.

Referring to FIG. 10A, in a non-limiting example, data flow in an iterative compression mode is illustrated. As a specific example, the description may be provided assuming that a system performance goal is “decompression latency of 250 nanoseconds (ns) or less and a compression ratio of 2.5 or greater” and the maximum number of iterations is set to 3.

First, in an example, the original data may initially be compressed by a compression device 1010, and a performance index may be calculated using a compression ratio calculator 1021 and a decompression latency predictor 1023. Here, initial predicted performance may be calculated as “the decompression latency of 270 ns and the compression ratio of 2.7”.

In an example, a recompression determination device 1025 may compare this result to target performance and may determine that the predicted latency (270 ns) does not satisfy the target (250 ns). Accordingly, the recompression determination device 1025 may activate a compression condition changing device 1030, which may change the compression parameter to reduce latency. As a result of performing recompression with the changed parameter, the performance may be improved to “the decompression latency of 260 ns and the compression ratio of 2.6”.

Since the improved performance still does not satisfy the latency target, the recompression determination device 1025 may determine to perform the iterative compression again within the maximum number of iterations. Finally, through the recompression, the performance of “the decompression latency of 240 ns and the compression ratio of 2.5” may be achieved, satisfying all target conditions. In this case, the recompression determination device 1025 may determine to terminate the compression, and the final compressed data may be selected through a MUX 1015 and may be output as a compressed block.

In another example of the iterative compression mode of FIG. 10A, a description of the case in which a trade-off occurs between performance indices may be provided. For example, in a specific operation during the iterative compression process, the performance may be “the decompression latency 260 ns and the compression ratio of 2.6,” which does not yet satisfy the latency target (250 ns) but satisfies the compression ratio target (2.5).

In this state, the recompression determination device 1025 may change the compression parameter again through the compression condition changing device 1030 to further improve the latency. However, as a result of performing recompression with the changed parameter, the performance may change to “the decompression latency of 245 ns and the compression ratio of 2.4.” This new result may satisfy the latency target, but the compression ratio may fall below the target value (2.5), failing to satisfy the final target condition.

In this case, the recompression determination device 1025 may determine to discard the current compression result and revert to the compression parameter used in the previous operation, just before the performance degradation. Subsequently, final compression may be performed once more using the parameter from the previous operation, and then the iterative compression may be terminated.

FIG. 10B illustrates an example of data flow in an uncompressed mode in detail according to one or more embodiments. The configuration and operation described with reference to FIGS. 1A to 9 may be applied in a similar manner or with some modifications to the example of FIG. 10B. Therefore, in the description of FIG. 10B, a detailed description of portions substantially similar to those described above with reference to FIGS. 1A to 9 may be omitted.

Referring to FIG. 10B, in a non-limiting example, data flow in an uncompressed mode is illustrated. The uncompressed mode according to an example may refer to an operation in which iterative compression is not performed. A first scenario illustrates a case in which an initial compression result does not satisfy the target performance. For example, initial prediction performance may be calculated as “the decompression latency of 270 ns and the compression ratio of 2.7”, failing to satisfy a latency target (250 ns). In this case, instead of attempting iterative compression, the recompression determination device 1025 may control the MUX 1015 to block an output of the compression device 1010 and for output, may select the original data from the input. Consequently, the uncompressed original data may be determined as the final output.

The second scenario illustrates a case in which the initial compression result immediately satisfies the target performance. For example, the initial prediction performance may be calculated as “the decompression latency of 240 ns and the compression ratio of 2.5”, satisfying all target conditions from the outset. In this case, the recompression determination device 1025 may determine that additional iterative compression is unnecessary and may allow the MUX 1015 to select the output of the compression device 1010 to output the initial compressed data as a final compressed block.

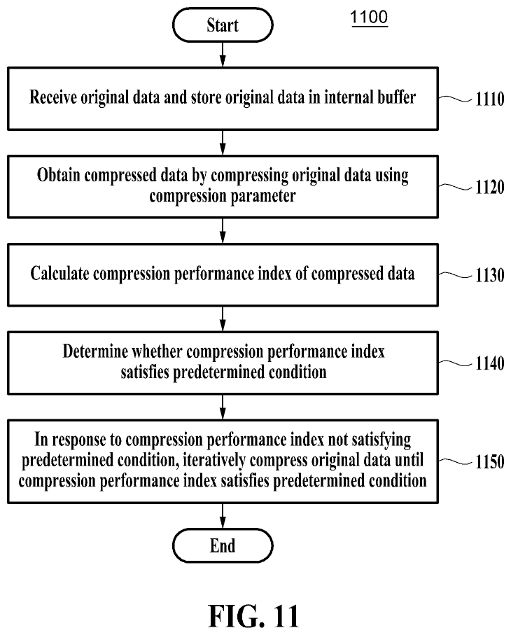

FIG. 11 illustrates an example method with compression according to one or more embodiments. The configuration and operation described with reference to FIGS. 1A to 10B may be applied in a similar manner or with some modifications to the example of FIG. 11. Therefore, in the description of FIG. 11, a detailed description of portions that are substantially similar to those described above with reference to FIGS. 1A to 10B may be omitted.

The operations of method 1100 may be performed in the described order and manner, but the order of some operations may be changed or some operations may be omitted without departing from the spirit and scope of the shown examples. Multiple operations shown in FIG. 11 may be performed in parallel or simultaneously.

Referring to FIG. 11, in a non-limiting example, method 1100 may include operation 1110, in which a compression engine (e.g., the compression engine 10 of FIG. 1A) may receive original data to be compressed and may store the original data in an internal buffer.

In an example, in operation 1120, the compression engine may compress the original data stored in the internal buffer using an initial compression parameter, thereby obtaining initial compressed data. The compression parameter may include, for example, at least one of a compression algorithm, a compression performing unit, a match threshold value, or a search window.

In an example, in operation 1130, the compression engine may calculate a compression performance index of the compressed data obtained in operation 1120. The calculating of the compression performance index may include calculating a compression ratio of the compressed data and estimating decompression latency of the compressed data. The compression ratio may be calculated by comparing the size of the original data to the size of the compressed data, and the decompression latency may be estimated based on a compression algorithm used and hardware characteristics of the decompression device.

In an example, in operation 1140, the compression engine may determine whether the compression performance index calculated in operation 1130 satisfies a predetermined condition. The predetermined condition may be determined based on one or more of the compression ratio, decompression latency, and the maximum number of iterative compressions.

For example, the determining of whether the compression performance index satisfies the predetermined condition may include determining whether the compression performance index satisfies a target threshold value within the maximum number of iterative compressions. When the compression performance index satisfies the predetermined condition, the compression engine may terminate the compression process and may generate a compressed block including the finally obtained compressed data and metadata.

In an example, in operation 1150, when the compression performance index does not satisfy the predetermined condition as a result of the determining in operation 1140, the compression engine may perform iterative compression on the original data until the performance index satisfies the condition.

In an example, the iterative compression operation may include changing the compression parameter based on a current compression performance index, recompressing the original data using the changed compression parameter to obtain new compressed data, updating (recalculating) the performance index for the new compressed data, and re-determining whether the updated performance index satisfies the predetermined condition.

For example, the iterative compression may be performed until the decompression latency falls below a certain threshold value or the number of iterations reaches a maximum. In another example, even if the decompression latency improves below a target threshold value during the iterative compression process, the compression ratio may still fall below another target threshold value. In this case, the compression engine may discard the current compression result, may perform final compression using the compression parameter before the compression parameter is changed, which is just before performance degradation, and may then terminate the iterative compression.

In another example, when the compression performance index is determined not to satisfy the predetermined condition in operation 1140, instead of performing the iterative compression in operation 1150, a non-compressed mode may be performed, in which the initial compressed data is replaced with the original data and the compression is terminated.

The hosts, compression devices, compression performance determination devices, compression condition changing devices, decompression devices, memories, comparators, AND gates, electronic devices, processors, host 100, compression device 110, compression performance determination device 120, compression condition changing device 130, decompression device 140, memory 150, comparator 410-1, comparator 410-2, AND gate 420, electronic device 900, memory 910, and processor 930 described herein, including descriptions with respect to respect to FIGS. 1-11, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-11 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A processor-implemented method, the method comprising:
compressing original data using a compression parameter to obtain compressed data;
calculating a compression performance index of the compressed data;
determining whether the compression performance index satisfies a predetermined condition; and
iteratively compressing the original data until the compression performance index satisfies the predetermined condition responsive to the compression performance index not satisfying the predetermined condition.

2. The method of claim 1, wherein the iteratively compressing comprises:
changing the compression parameter based on the compression performance index;
compressing the original data using the changed compression parameter to obtain new compressed data;
updating the compression performance index for the new compressed data; and
determining whether the updated compression performance index satisfies the predetermined condition.

3. The method of claim 1, wherein the determining of whether the compression performance index satisfies the predetermined condition comprises:
determining whether the compression performance index satisfies the predetermined condition within a maximum number of iterative compressions.

4. The method of claim 1, wherein the calculating of the compression performance index comprises:
calculating a compression ratio of the compressed data; and
predicting decompression latency of the compressed data.

5. The method of claim 4, wherein the predetermined condition is determined based on one or more of a number of iterative compressions, the compression ratio, or the decompression latency.

6. The method of claim 2, wherein the iteratively compressing comprises:
iteratively compressing the original data until a decompression latency becomes less than or equal to a first threshold value or a number of iterative compressions reaches a maximum number of iterations.

7. The method of claim 6, wherein the iteratively compressing comprises:
even if the decompression latency becomes less than or equal to the first threshold value, and responsive to a compression ratio becoming less than or equal to a second threshold value, performing compression on the original data using the compression parameter before the compression parameter is changed and terminating the iterative compressions.

8. The method of claim 1, further comprising:
replacing the compressed data with the original data without performing the iteratively compressing responsive to the compression performance index not satisfying the predetermined condition.

9. The method of claim 1, further comprising:
after the iteratively compressing is completed, generating a compressed block comprising final compressed data, and metadata corresponding to the final compressed data,
wherein the metadata comprises one or more of information about a compression parameter resulting from the iterative compression, information about a compression ratio threshold value, information about a decompression latency threshold value, and information about a maximum number of iterations.

10. The method of claim 4, wherein the calculating of the compression ratio comprises:
comparing a size of the original data to a size of the compressed data to calculate the compression ratio.

11. The method of claim 4, wherein the predicting of the decompression latency comprises
calculating the decompression latency based on characteristics of a compression algorithm and a decompression device.

12. The method of claim 11, wherein the compression parameter includes one or more of the compression algorithm, a compression performing unit, a match threshold, or a search window.

13. The method of claim 12, wherein the changing of the compression parameter comprises:
setting a compression parameter combination based on one or more of the compression algorithm, the compression performing unit, the match threshold, or the search window; and
determining the compression parameter combination based on the compression performance index.

14. A non-transitory, computer-readable storage medium storing instructions that, when executed by one or more processors, configure the one or more processors to:
determine a compression performance index of compressed data;
determine whether the compression performance index satisfies a predetermined condition; and
iteratively compress original data, the compressed data being based on the original data, until the compression performance index satisfies the predetermined condition responsive to the compression index not satisfying the predetermined condition.

15. An electronic device, comprising:
one or more processors comprising processing circuitry; and
a memory comprising one or more storage media storing instructions that, when executed individually or collectively by the one or more processors, cause the electronic device to:
calculate a compression performance index of compressed data, the compressed data being obtained from original data;
determine whether the compression performance index satisfies a predetermined condition; and
iteratively compress the original data until the compression performance index satisfies the predetermined condition responsive to the compression index not satisfying the predetermined condition.

16. The electronic device of claim 15, further comprising:
an internal buffer configured to receive and store the original data.

17. The electronic device of claim 15, wherein the memory is configured to store one or more of information about a compression ratio threshold value, information about a decompression latency threshold value, or information about a maximum number of iterations.

18. The electronic device of claim 15, wherein the instructions, when individually or collectively executed by the one or more processors, cause the electronic device to:
change the compression parameter based on the compression performance index;
compress the original data using the changed compression parameter to obtain new compressed data;
update the compression performance index for the new compressed data; and
determine whether the updated compression performance index satisfies the predetermined condition.

19. The electronic device of claim 15, wherein the instructions, when individually or collectively executed by the one or more processors, cause the electronic device to:
determine whether the compression performance index satisfies the predetermined condition within a maximum number of iterative compressions.

20. The electronic device of claim 15, wherein the instructions, when individually or collectively executed by the one or more processors, cause the electronic device to:
calculate a compression ratio of the compressed data; and
predict decompression latency of the compressed data.
